(19) United States
(12) Patent Application Publication
(10) Pub. No.: US 2023/0243876 A1
(43) Pub. Date: Aug. 3, 2023

(54) METHOD AND SYSTEM FOR MONITORING A MACHINE STATE

(71) Applicant: Siemens Aktiengesellschaft, 80333 München (DE)

(72) Inventor: JÜRGEN ZETTNER, Veitsbronn (DE)

(73) Assignee: Siemens Aktiengesellschaft, 80333 München (DE)

(21) Appl. No.: 18/023,636

(22) PCT Filed: Aug. 13, 2021
(86) PCT No.: PCT/EP2021/072634

§ 371 Date: Feb. 27, 2023

(30) Foreign Application Priority Data
Aug. 28, 2020 (EP) 20193335.5

(51) Int. Cl. G01R 23/165; G01R 19/00; G01R 31/34

(52) U.S. Cl. CPC G01R 23/165; G01R 19/0007; G01R 31/343

(57) ABSTRACT

A method for monitoring the state of an electric machine includes determining within a defined frequency range, for example in a spectrogram of a current amplitude, a frequency position where a current amplitude has a maximum at the frequency position and where a phase relationship between a current vector and a voltage vector or between two current vectors is located in a predefined interval. The determined frequency position is characteristic; of the state of the electric machine.

The invention relates to a method, preferably a computer-implemented method, and a system for monitoring the state of an electric machine.

The invention also relates to a computer program code comprising the commands for performing the aforesaid method.

The invention further relates to a data carrier signal which transmits the aforesaid computer program code.

In the monitoring of electric machines, the technique known as motor current signature analysis (MCSA) is used as a possible condition monitoring (CM) tool and is well-known in the prior art (cf. D. Miljković “Brief Review of Motor Current Signature Analysis”, CrSNDT Journal, 5. 14-26. (2015); H.W. Penrose, “Practical Motor Current Signature Analysis; Taking the Mystery Out of MCSA”, ALL-TEST Pro (2003); C. Kar and A.R. Mohanty, “Monitoring gear vibrations through motor current signature analysis and wavelet transform”, Mechanical Systems and Signal Processing, Vol. 20, Issue 1, January 2006, pp. 158-187).

In MCSA, a Fourier transform (FFT), for example, is applied in order to detect or quantify fault conditions and/or operating states of electric machines in the frequency domain. Conventional MCSA is applied here in the quasistationary case, i.e. in the case of nominally constant rotational speed. Analysis using short-time FFTs or wavelets constitutes an extension of MCSA in order to analyze processes in a temporally resolved manner.

To supplement MCSA, spectral components of the voltage (MVSA) can be called upon in addition in order to conduct the condition monitoring (cf. Kumar, K. (2011), “A Review of Voltage and Current Signature Diagnosis in Industrial Drives”, International Journal of Power Electronics and Drive Systems (IJPEDS). 1. 10.11591/ijpeds.v1i1.64).

With this approach—in the case of three-phase motors—three electrical phases (R, S, T) of the propulsion technology are measured. In addition to the current I, measuring instruments also measure the voltage U of the phases. The measurement is carried out at a high sampling frequency and as far as possible synchronously in time.

One task of MCSA is to determine the slip of asynchronous machines (ASMs) with a maximum degree of accuracy. If, for instance, there is even just a slight change in the load conditions, the ASM responds by adjusting the rotational speed. One means of determining the slip exactly is by determining the frequency of what are termed the principal slot harmonics (PSH). For this purpose, the PSH frequencies f_{PSH}, which are a function of the number of rotor bars R, the number of pole pairs p and the slip s (f_{PSH}=func(R,p,s)), in one or more electrical phases (R,S,T) of the detected currents in the respective motor are evaluated. One problem here is that the amplitudes outside the electrical power supply grid frequency f0 (typically 50 Hz or 60 Hz) express themselves as very small<1e-2*A(f0) compared to the amplitude of the supply current (A(f0)). The measured current amplitudes in the frequency ranges of the PSH can become very small and, depending on the required temporal resolution of the evaluation, are affected by noise and interferences which can lie in the range of the amplitudes that are to be determined for slip detection. Dynamic slip detection with PSH is therefore susceptible to interferences and is therefore too imprecise. Among other things, interferences can be the grid voltage components of other power-consuming loads in the power supply grid.

However, the aforesaid disadvantages relate not only to a frequency determination in the case of the PSH. Rather, similar problems exist with all MCSA frequency determinations which indicate the detection of deviations or faults and should allow a condition monitoring diagnosis. Faults such as rotor bar breakage, eccentricities, bearing failure, effect of coupled machines, but precisely also the load state of the machine are required to be detected in the current spectrum in the MCSA prior art at known frequencies assignable to said fault conditions or operating states.

If, for example, amplitudes are found or determined at those frequencies that are characteristic of a particular fault condition or operating state, for example an eccentricity of the air gap, then this is to be attributed to the aforementioned particular fault condition or operating state of the electric machine.

MCSA makes use of the assumption of constant ratios and averaging over long periods of time (typical measurement times here are approx. 30 s) in order to improve the SNR (signal-to-noise ratio) of the signals. In this case it is only possible to determine an averaged slip over the measurement time or a fault amplitude from averaged values of the associated amplitudes at damage frequencies.

The object of the present invention can therefore be seen as to develop the condition monitoring methods and systems for electric machines and to enable a dynamic frequency position or frequency line detection and for example a dynamic slip detection.

The object is achieved according to the invention by means of a method as cited in the introduction in that within a defined frequency range, for example in a spectrogram of a current amplitude (acquired by means of a measurement), a frequency position or line is determined in such a way that the current amplitude is at a maximum at the frequency position or line and a phase relationship between a current vector and a voltage vector or between two current vectors lies in a predefined interval (or a phase relationship (at maximum current amplitude) is determined by means of a phase filter), the determined frequency position or line being characteristic of a state of the electric machine.

In other words, during the determination of the frequency line, the current amplitude and a phase relationship between a current vector and a voltage vector or between two current vectors (depending on the frequency) are determined and a check is carried out to establish whether the current amplitude is at a maximum at the frequency and (at the same time) the phase relationship between a current vector and a voltage vector or between two current vectors (at the frequency) lies in a predefined interval. If it is established in the process that these two conditions are met, i.e. the current amplitude is at a maximum and the phase relationship between a current vector and a voltage vector or between two current vectors lies in a predefined interval, the frequency at which the two conditions have been positively checked is specified as a frequency of the frequency line or position that is to be determined.

The interval is predefined in such a way that the frequency position (the frequency line of interest=the “main line”) has a first (absolute) phase position (e.g. 60° to 80°) which is preferably well-defined, whereas the fault lines, e.g. sideband lines, have a phase position that deviates therefrom (e.g. 0° to 20°. The interval is therefore predefined in order to differentiate between the main line(s) and the fault ones. “Predefined” thus relates to the ability to distinguish the main line(s) from fault lines in the phase. In other words, the selection of a “predefined” (phase) interval (in a frequency band around the main line) is to be made such that the ability to distinguish phase positions from interfering fault lines is made possible, is preferably increased, in particular is maximized.

It can be beneficial to define the frequency range in such a way that at least one frequency line characteristic of a state of the electric machine lies or could lie in the frequency range (the possible position of a frequency line can be found for example using the MCSA method). This enables an assignment of a frequency range to a frequency line that is characteristic of a state of the electric machine to take place.

To sum up, with the method, a frequency position or line is determined within a defined frequency range, for example in a spectrogram of a current amplitude (acquired by means of a measurement), as a function of the current amplitude and of a phase relationship between a current vector and a voltage vector or between two current vectors. In this case the current amplitude is to be maximized and the phase relationship is to lie in a predefined interval. The determined frequency position or line is characteristic of a state of the electric machine.

As already described, the determined frequency position or line is assigned to a (specific) state of the electric machine and thus permits inferences to be made about said (specific) machine state.

In one embodiment, it can advantageously be provided that within a plurality of different, preferably non-overlapping, predefined frequency ranges, a frequency position is determined in each case, different frequency positions or lines being characteristic of different states of the electric machine.

In one embodiment, it can be beneficial if the electric machine is a three-phase machine and the state of the machine is a fault condition or an operating state.

In one embodiment, it can be advantageous if the three-phase machine is an asynchronous machine and the frequency range is determined by a slip range between 0 and breakdown slip, in particular by a slip range between approx. 5% and approx. 10% (typical slip values for asynchronous machines 5 to 30 KW).

In one embodiment, it can advantageously be provided that the three-phase machine is a synchronous machine and the state is a fault condition. In this case no slip detection and consequently no load evaluation as in the case of ASM is performed, but instead a fault frequency evaluation is carried out.

In one embodiment, it can be beneficial if the phase relationship is a phase relationship between an α and a β current vector. The α, β current vectors are the current vectors resulting from a Clarke transformation or an α,β transformation. This transformation is familiar to the person skilled in the art and serves to convert multiphase variables such as in the case of a three-phase machine having the axes U, V, W, . . . into a simpler two-axis coordinate system having the axes α, β.

In one embodiment, it can be provided that the predefined interval is an interval between approx. 40° and approx. 90°, preferably between approx. 40° and approx. 60° or between approx. 70° and approx. 90°, in particular between approx. 80° and approx. 90°.

In one embodiment, it can be provided that the phase relationship is determined from or on the basis of or using admittance or impedance.

In one embodiment, it can advantageously be provided that the current amplitude is measured over a predefined measurement time amounting, for example, to between approx. 0.1 second and 10 seconds, for example between approx. 1 second and 10 seconds, preferably between approx. 1 second and 5 seconds, in particular 1 second.

In order to generate spectrograms, it is possible to choose a short measurement time for current and/or voltage, as described above. This is advantageous and enables a dynamic evaluation of operating states and/or fault conditions. In this case the measurement time is shorter than the measurement time for the typical MCSA, which lies in the region of approx. 30 seconds.

The object is also achieved according to the invention by means of a system as cited in the introduction in that the system comprises a computing unit, the computing unit having a computer program code, the computer program code comprising commands which, when the program code is executed by the computing unit, cause the latter to perform the aforesaid method.

In one embodiment, it can be beneficial if the system additionally has a measurement unit for measuring the current and/or voltage of a three-phase machine, in particular a synchronous or an asynchronous machine.

The state/condition monitoring method and the system according to the invention enable a more robust and more accurate determination of a frequency position in a predefined frequency range at the maximum amplitude. From this, e.g. slip can be determined more robustly and/or malfunctions ruled out more reliably. This permits for example a dynamic measurement e.g. of load variations, a knowledge of the slip at one-second intervals, etc.

The invention is described and explained in more detail below with reference to the exemplary embodiments illustrated in the figures, in which:

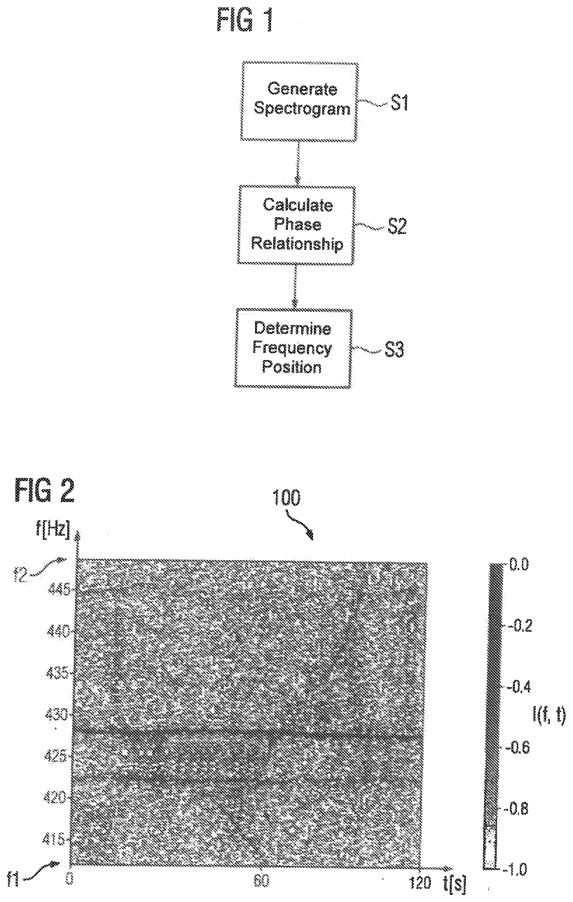

FIG 1 shows a flowchart of a computer-implemented method for monitoring the state of an electric machine,

FIG. 2 shows a detail from a spectrogram,

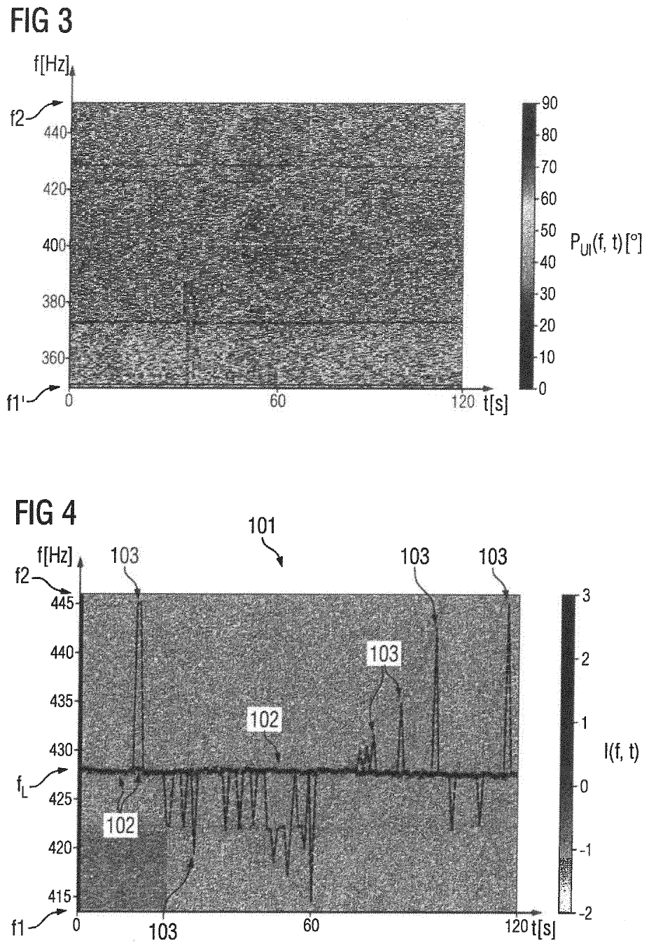

FIG. 3 shows a phase relationship between a current vector and a voltage vector,

FIG. 4 shows phase positions determined with and without taking the phase relationship of FIG. 3 into account,

FIG. 5 shows a phase relationship between an α and a β current vector,

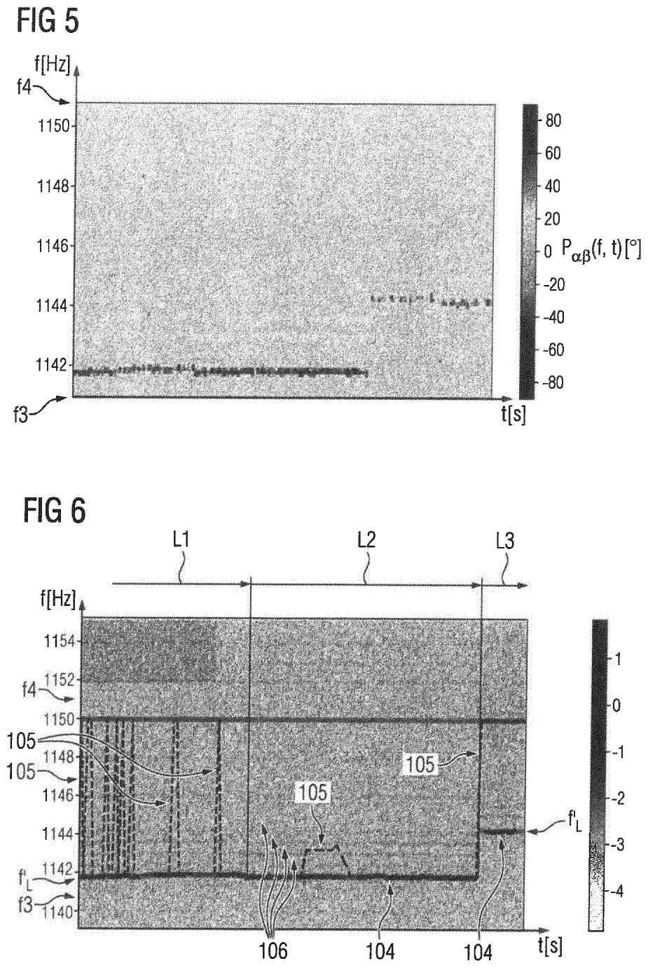

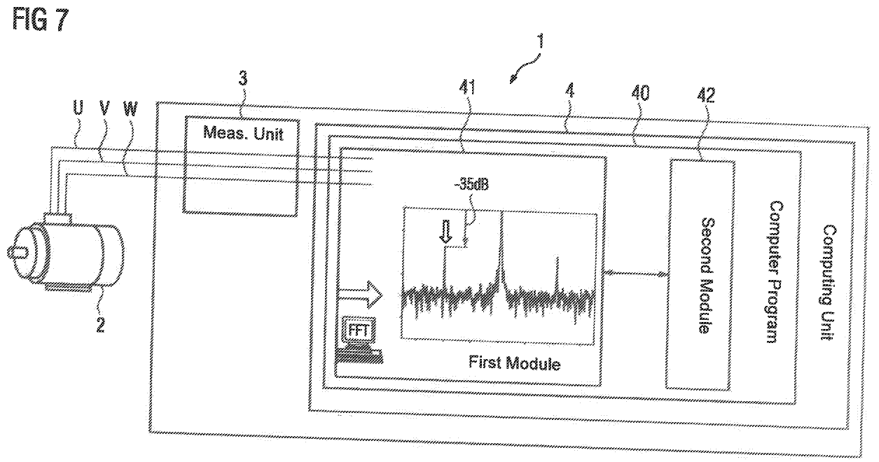

FIG. 6 shows phase positions determined with and without taking the phase relationship of FIG. 5 into account, and

FIG. 7 shows a state/condition monitoring system for an asynchronous motor.

FIG. 1 shows a flowchart of a computer-implemented method for monitoring the state or condition of an electric machine, the computer-implemented method corresponding to the method according to the invention.

In a step S1 of the method, a spectrogram I(f,t) of a current amplitude can be generated (on the basis of the measured current values). An exemplary detail (frequencies between approx. 410 Hz and 450 Hz) of the spectrogram 100 is shown in FIG. 2. The detail shows a defined frequency range (f1, f2)—in this case between approx. 410 Hz (f1) and approx. 450 Hz (f2). With three-phase machines, in particular in the case of asynchronous machines, the defined frequency range (f1, f2) can comprise one of the known damage frequencies, such as e.g. a rotor bar breakage frequency, which were determined previously by means of a motor current signature analysis (MCSA) method according to the prior art.

In a step S2 of the method, a phase relationship (in degrees) is calculated for example between a current vector and a (previously measured) voltage vector (I and U). The calculated phase angle P_{UI}(f,t) between the current vector and the voltage vector for the spectrogram 100 in a frequency range (f1, f2) between approx. 350 Hz (f1′) and approx. 450 Hz (f2) is apparent from FIG. 3. The phase relationship P_{UI}(f,t) can be determined for example from or on the basis of or using admittance or impedance.

A current and/or voltage measurement which serves to generate the spectrogram 100 and/or the phase relationship can be conducted over a predefined measurement time, A current and/or voltage measurement which has a measurement time per measurement of approx. 0.1 second to 10 seconds, in particular one second, is particularly advantageous. This allows a dynamic evaluation of operating states and/or fault conditions. In this case the measurement time is shorter than the measurement time for a typical motor current signature analysis (MCSA), in which the measurement time lies in the region of approx. 30 seconds.

In a step S3 of the method, a frequency position f_{L} within the defined frequency range (f1, f2) (cf. the spectrogram 100 or 101) is determined in such a way that, at the frequency position f_{L}, the current amplitude I(f,t) is at a maximum and the phase relationship P_{UI}(f,t) lies in a predefined interval.

The frequency position f_{L} can correspond for example to a principal slot harmonics (PSH) frequency of a three-phase asynchronous machine, the frequency f_{PSH}(7n) being for example approx. 427 Hz.

The PSH frequencies are a function of the number of rotor bars R, the number of pole pairs p and the slip s (f_{PSH}=func(R,p,s)). If a PSH frequency is now determined more precisely/more reliably, the slip, for example, can also be determined more precisely/more reliably.

In particular in the case of three-phase machines, the frequency range (f1, f2) can be given by a slip range between 0 and breakdown slip, in particular by a slip range between approx. 5% and approx. 10% (a slip range can be converted into a frequency range). The slip range between approx. 5% and approx. 10% contains typical slip values for asynchronous machines with power ratings between approx. 5 KW and approx. 30 KW.

In other words, when the current amplitude I(f,t) is being determined, a phase filter is applied in order to distinguish between actually measured currents and fault-induced current signature amplitudes which can result due to interferences/noise caused for example by grid voltage components of other power-consuming loads in the power supply grid, and to exclude the fault-induced current signature amplitudes.

The predefined interval can comprise for example angles between approx. 40° and approx. 90°. In the example of the method shown here (FIGS. 2 to 4), in which the phase relationship P_{UI} between a current vector and a voltage vector is determined, the phase filter can be set for angles between approx. 70° and approx. 90°, for example between approx. 80° and approx. 90 . Generally, the interval should be chosen such that the angles included in the interval describe a phase which is possible between the actually measured current vectors and voltage vectors or which makes sense physically.

In the case of the aforementioned fault-induced current signature amplitudes, which are roughly equal in magnitude to the measured current amplitudes, the phase relationship in the phase image shown in FIG. 3 lies in the range of approx. 20° to 30°, with the result that the fault-induced current signature amplitudes are filtered out by means of the phase filter.

The determined frequency position f_{L} is characteristic of a state of the electric machine or, as the case may be, the determined frequency position f_{L} is assigned to a (specific) state of the electric machine.

Once the state of the machine has been determined on the basis of the identified frequency position f_{L}, the machine can be controlled accordingly. For example, should it be detected that the state of the machine is critical due to a broken rotor bar, the machine can be switched off. Should the state of the machine still be acceptable but it is detected that the critical state is likely imminent, a corresponding warning message can be output, for example.

In the case of three-phase machines, the frequency position f_{L} can be assigned for example to one of the following fault conditions: air gap eccentricity, rotor bar breakage (in the case of asynchronous machines), bearing breakage/failure, stator winding fault.

Furthermore, a load state of a three-phase machine can be assigned to the frequency position f_{L.}

FIG. 4 shows a spectrogram 101 on which the determined frequency position f_{L} is plotted. FIG. 4 illustrates an improvement in slip detection 102 (crosses) compared to the conventional evaluation 103 (dashed line) in a permitted slip range, for example between 0 and breakdown slip, preferably between 5% and 10%, which is affected by interference frequencies. This improvement is achieved by adding the aforementioned phase information during the determination of the frequency position.

FIG. 5 shows a further possible phase relationship P_{αβ}(f,t), which can be calculated during the aforementioned step S2 of the method. The phase angle P_{αβ}(f,t) shown in FIG. 5 is a phase angle between two phase currents I_{α}and f_{β}, which can be obtained from three phase currents I_{U}, I_{V}, I_{W}, of a three-phase machine by means of a Clarke transformation.

The phase relationship P_{αβ}(f,t) can be calculated for example in a frequency range (f3, f4) between approx. 1140 Hz (f3) and approx. 1151 Hz (f4).

The frequency position f′_{L} corresponds to a PSH frequency (7n). The predefined interval (of the phase filters) comprises angles between approx. 40° and approx. 60°.

FIG. 6 shows the determined frequency position f′_{L}. Also to be seen in FIG. 6 is a slip 104 (crosses) determined on the basis of the identified frequency position f′_{L} compared to the conventional evaluation 105 (dashed line) in a permitted slip range which is affected by interference frequencies that are attributable for example to existing sidebands 106 or voltage changes.

It is also clear from FIG. 6 that the identified frequency position f′_{L} also provides information about a load state L1, L2, L3 and allows this to be determined very much more precisely.

The above-described method can also be performed within a plurality of different, preferably non-overlapping, predefined frequency ranges. Here, a frequency position can be identified in each frequency range in each case, wherein different frequency positions or lines can be characteristic of different states of the electric machine.

It is furthermore apparent from the overall view provided by FIG. 5 and FIG. 6 how the predefined interval is used in order to select the right frequency position. One frequency position (the frequency line of interest=the “main line”) for the description of a state (the approximate position of which can be determined e.g. with the aid of a conventional MCSA evaluation) has a well-defined absolute phase position (in FIG. 5 e.g. 60-80°, dark), whereas interference ones, e.g. sideband lines (clearly visible in FIG. 6), have a phase position that deviates therefrom (in FIG. 5 0-20°, bright).

The selection of a “predefined” phase interval in a frequency band around the main line can therefore be made in such a way that the ability to differentiate phase positions from interfering lines is made possible, is preferably increased, in particular is maximized,

The (phase) filter can be realized e.g. in such a way that Y(f,t)=X(f,t)*phase filter(f,t),

where phase filter(f,t)=0 if P(f,t) is outside, phase filter (f,t)=1 if P(f,t) is inside the predefined interval. This enables interferences in the amplitude to be filtered out, the equation Y(f,t)=X(f,t) remaining unchanged where the phase position of the main line lies.

FIG. 7 shows a system 1 for monitoring the state of an electric machine which is embodied for example as a three-phase U, V, W asynchronous machine 2. The system 1 comprises a measurement unit 3 for measuring currents and/or voltages at the three-phase asynchronous machine 2 and a computing unit 4. The computing unit 4 has a computer program 40. The computer program 40 can be resident on a computer-readable volatile or non-volatile medium of the computing unit 4.

The computer program 40 can comprise two modules 41, 42, wherein the first module 41 can comprise instructions which, when the first module 41 is executed by the computing units 4, cause the latter to evaluate spectral amplitudes on known damage frequencies for example by means of Fourier or wavelet transform. The second module 42 can in this case comprise instructions which, when the second module 42 is executed by the computing units 4, cause the latter to identify a frequency position f_{L}, f′_{L} in accordance with the above-cited method steps S1 to S3 and preferably determine the slip and/or the load state of the asynchronous machine 2.

Each of the modules 41 and 42 can also be embodied as a computer program. In this case it can be beneficial to make a corresponding spectrogram 100 available to the computer program 42.

Although the invention has been illustrated and described in greater detail on the basis of exemplary embodiments, the invention is not limited by the disclosed examples. Variations hereof may be derived by the person skilled in the art without leaving the scope of protection of the invention as defined by the following claims. In particular, the features described in connection with the method can also find application in the system or, as the case may be, complete the latter, and vice versa.

1.-13. (canceled)

14. A method for monitoring a state of an electric machine, comprising:
determining within a defined frequency range a frequency position that is characteristic of a state of the electric machine; and
determining at the frequency position a current amplitude having a maximum value and a phase relationship between a current vector and a voltage vector or between two current vectors located in a predefined interval.

15. The method of claim 14, further comprising determining, within a plurality of different predefined frequency ranges, for each range a frequency position that is characteristic of different states of the electric machine.

16. The method of claim 15, wherein the different predefined frequency ranges are non-overlapping.

17. The method of claim 14, wherein the electric machine is a three-phase machine and the state of the machine is a fault condition or an operating state.

18. The method of claim 17, wherein the three-phase machine is an asynchronous machine and the frequency range is determined for a slip range between 0 and a breakdown slip.

19. The method of claim 18, wherein the slip range is between 5% and 10%.

20. The method of claim 17, wherein the three-phase machine is a synchronous machine and the state of the machine is a fault condition.

21. The method of claim 14, wherein the phase relationship is a phase relationship between an a current vector and a β current vector.

22. The method of claim 14, wherein the predefined interval is an interval between 40° and 90°, in particular between 40° and 60° , or between 70° and 90°.

23. The method of claim 14, wherein the predefined interval is an interval between 40° and 60°.

24. The method of claim 14, wherein the predefined interval is an interval between 70° and 90°.

25. The method of claim 14, wherein the phase relationship is determined from an admittance or an impedance.

26. The method of claim 14, further comprising measuring the current amplitude over a predefined measurement time of between approx. 0.1 second and 10 seconds.

27. The method of claim 14, further comprising measuring the current amplitude over a predefined measurement time of between approx. 1 second and 10 seconds.

28. The method of claim 14, further comprising measuring the current amplitude over a predefined measurement time of between approx. 1 second and 5 seconds.

29. The method of claim 14, further comprising measuring the current amplitude over a predefined measurement time of 1 second.

30. A computer program code stored on a non-transitory computer-readable medium and comprising commands which, when read into a memory of a computer and executed by a processor of the computer, cause the computer to perform a method as set forth in claim 14.

31. A system for monitoring a state of an electric machine, comprising a computing unit with a processor which executes a computer program code as as set forth in claim 30.

32. The system of claim 31, further comprising a measurement unit configured to measure a current or a voltage of a three-phase machine.

33. A data carrier signal, configured to transmit a computer program code as set forth in claim 30.
